(19) United States
(12) Patent Application Publication
(10) Pub. No.: US 2007/0047327 A1
(43) Pub. Date: Mar. 1, 2007

(54) Erase method for flash memory

(75) Inventors: Akira Goda, Boise, ID (US); Seiichi Aritome, Boise, ID (US)

Correspondence Address: LEFFERT JAY & POLGLAZE, P. A.;Attn: Andrew C. Walseth, P. O. Box 581009, Minneapolis, MN, 55402, US

(73) Assignee: Micron Technology, Inc.

(21) Appl. No.: 11/215,940

(22) Filed: Aug. 31, 2005

(51) Int. Cl. G11C 16/04

(52) U.S. Cl. 365/185.29

(57) ABSTRACT

A non-volatile memory device and programming process is described that erases blocks of non-volatile memory cells by the application of differing word line erase voltages to selected word lines during an erase cycle. This facilitates for a faster on average erase operation, a tighter erased cell Vt distribution, an increase in memory device endurance and lifetimes due to a decrease in memory cell overerasure and overstress, and a more accurate match of word line voltages to the specific non-volatile memory array, the specific region or row being programmed, and any changes in programming characteristics due to device use and wear. In one embodiment of the present invention, the differing word line erase voltages are utilized to compensate for faster and slower erasing word lines. In another embodiment, different word line erase voltages are applied based on physical aspects of the word lines of the array.

### TECHNICAL FIELD OF THE INVENTION

The present invention relates generally to memory devices and in particular the present invention relates to Flash memory devices.

### BACKGROUND OF THE INVENTION

Memory devices are typically provided as internal storage areas in the computer. The term memory identifies data storage that comes in the form of integrated circuit chips. There are several different types of memory used in modern electronics, one common type is RAM (random-access memory). RAM is characteristically found in use as main memory in a computer environment. RAM refers to read and write memory; that is, you can both write data into RAM and read data from RAM. This is in contrast to ROM, which permits you only to read data. Most RAM is volatile, which means that it requires a steady flow of electricity to maintain its contents. As soon as the power is turned off, whatever data was in RAM is lost.

Computers almost always contain a small amount of read-only memory (ROM) that holds instructions for starting up the computer. Unlike RAM, ROM cannot be written to. Memory devices that do not lose the data content of their memory cells when power is removed are generally referred to as non-volatile memories. An EEPROM (electrically erasable programmable read-only memory) is a special type non-volatile ROM that can be erased by exposing it to an electrical charge. EEPROM comprise a large number of memory cells having electrically isolated gates (floating gates). Data is stored in the memory cells in the form of charge on the floating gates. A typical floating gate memory cell is fabricated in an integrated circuit substrate and includes a source region and a drain region that is spaced apart from the source region to form an intermediate channel region. A conductive floating gate, typically made of doped polysilicon, or non-conductive charge trapping layer (a floating node), such as nitride (as would be utilized in a silicon-oxide-nitride-oxide-silicon or SONOS gate-insulator stack), is disposed over the channel region and is electrically isolated from the other cell elements by a dielectric material, typically an oxide. For example, a tunnel oxide that is formed between the floating gate and the channel region. A control gate is located over the floating gate/node and is typically made of doped polysilicon or metal. The control gate is electrically separated from the floating gate by another dielectric layer. Thus, the floating gate or charge trapping layer is “floating” in dielectric so that it is insulated from both the channel and the control gate. Charge is transported to or removed from the floating gate or trapping layer by specialized programming and erase operations, respectively, altering the threshold voltage of the device.

Yet another type of non-volatile memory is a Flash memory. A typical Flash memory comprises a memory array, which includes a large number of memory cells. Each of the memory cells includes a floating gate or charge trapping layer embedded in a field effect transistor (FET) transistor. The cells are usually grouped into sections called “erase blocks.” Each of the cells within an erase block can be electrically programmed selectively by tunneling charges to the floating gate. The negative charge is typically removed from the floating gate/node by a block erase operation, wherein all floating gate/node memory cells in the erase block are erased in a single operation. It is noted that in recent Flash memory devices multiple bits have been stored in a single cell by utilizing multiple threshold levels or a non-conductive charge trapping layer with the storing of data trapped in a charge near each of the sources/drains of the memory cell FET.

In prior art Flash memory erase operations, the unprogrammed memory cells of the erase block selected for erasure are first pre-programmed to bring the memory cells of the erase block to a more uniform state and help prevent overerasure. A block erase operation is then performed to erase the memory cells by applying an erasure voltage to the substrate (or alternatively, the channels of the memory cell) and a ground voltage to the word lines coupled to the control gates of the memory cells. This applies an erase field that across the memory cells that causes the carriers stored on the floating gates and/or charge trapping layers to be removed and the memory cells placed in an erased state with an erased threshold voltage level. An erase verify operation is then performed on the erase block to confirm that the memory cells have been erased below a minimum erase threshold voltage level. If memory cells of the erase block have failed erase verification, the erase and verify cycle is repeated until the erase block is erased or a selected number of iterations have passed and the erasure of the erase block is deemed to have failed erasure.

A problem in erasing Flash memory devices is that different word lines in a given erase block can have faster or slower erase characteristics due to issues that can include, but are not limited to, different word line resistance, the word line physical placement in the memory array, and the word line coupling to the memory cells and other adjacent elements and word lines of the memory array. Because of this, the threshold voltage distribution of the erased memory cells can be skewed, with slower erasing word lines getting undererased (possibly causing additional erase and verify cycles) and faster erasing word lines being potentially overerased and overstressed (decreasing the lifespan of the affected memory cells and the endurance of the erase block).

For the reasons stated above, and for other reasons stated below which will become apparent to those skilled in the art upon reading and understanding the present specification, there is a need in the art for alternative methods of erasing Flash memory arrays.

### SUMMARY

The above-mentioned problems with erasing Flash memories and other problems are addressed by the present invention and will be understood by reading and studying the following specification.

The various embodiments relate to non-volatile memory devices wherein differing word line voltages are utilized in the erasure of blocks of non-volatile memory cells (such as floating gate or floating node/charge trapping memory cells). In one embodiment of the present invention, the differing word line erase voltages are utilized to compensate for faster and slower erasing word lines. In another embodiment, different word line erase voltages are applied based on physical aspects of the word lines of the array, including, but not limited to, an interlaced array of alternating wide/thin cross section word lines which have higher/lower word line resistances and/or capacitive coupling ratios with the underlying non-volatile memory cells. In embodiments of the present invention, two or more voltage levels can be applied to the word lines of the erase block selected for erasure. In one embodiment of the present invention, the word line erase voltages are selected before beginning erasure based on known fast or slow erasing word lines. In another embodiment, the word line voltages can be iteratively adjusted for each following erase cycle of a block erase operation based on the results of the erase verification. In yet another embodiment of the present invention, the word line voltages are adjusted to compensate word lines or memory cells that are vulnerable to disturb by erasing them deeper or shallower than the rest of the erase block. In a further embodiment, the following erase cycles of an erase operation are repeated with differing word line erase voltage levels on selected word lines that failed verification to erase the memory cells that failed to erase correctly in the previous cycles.

For one embodiment, the invention provides a method of erasing memory cells comprising applying two or more word line erase voltages to a plurality of word lines, each word line coupled to one or more non-volatile memory cells of a non-volatile memory array having a plurality of non-volatile memory cells, and applying an erase voltage to a substrate connection of the non-volatile memory cells coupled to the plurality of word lines to erase the memory cells.

In another embodiment, the invention provides a non-volatile memory device comprising a non-volatile memory array having a plurality of erase blocks, and a control circuit, wherein the control circuit is adapted to erase a selected erase block of the non-volatile memory array by, applying two or more voltages to a plurality of word lines, each word line coupled to one or more non-volatile memory cells of the selected erase block, and applying an erase voltage to a substrate connection of the non-volatile memory cells of the erase block to erase the memory cells.

Further embodiments of the invention include methods and apparatus of varying scope.

### BRIEF DESCRIPTION OF THE DRAWINGS

FIG. 1 is a simplified block diagram of a system containing a non-volatile memory device in accordance with an embodiment of the present invention.

FIGS. 2A and 2B are simplified block diagrams of NAND and NOR architecture Flash memory arrays in accordance with an embodiment of the present invention.

FIGS. 3A-3D shows a flowchart and simplified diagrams of a typical prior art flash memory array erase and verify operation.

FIGS. 4A and 4B show diagrams detailing typical prior art Vt distribution of erased floating gate memory cells.

FIGS. 5A and 5B show diagrams detailing the Vt distribution of erased floating gate/floating node memory cells in accordance with an embodiment of the present invention.

FIGS. 6A-6H detail word line voltages of an erase operation of a NAND architecture Flash memory in accordance with embodiments of the present invention.

FIGS. 7A-7D detail flowcharts of erase and verify operations of a Flash memory in accordance with various embodiments of the present invention.

FIG. 8 is a simplified block diagram of a memory module in accordance with an embodiment of the present invention.

### DETAILED DESCRIPTION

In the following detailed description of the preferred embodiments, reference is made to the accompanying drawings that form a part hereof, and in which is shown by way of illustration specific preferred embodiments in which the inventions may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The terms wafer or substrate used in the following description include any base semiconductor structure. Both are to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a wafer or substrate in the following description, previous process steps may have been utilized to form regions/junctions in the base semiconductor structure, and terms wafer or substrate include the underlying layers containing such regions/junctions. The following detailed description is, therefore, not to be taken in a limiting sense, and the scope of the present invention is defined only by the claims.

Embodiments of the present invention include non-volatile memory devices that erase blocks of non-volatile memory cells by the application of differing word line erase voltages to selected word lines during an erase cycle. This facilitates a faster on average erase operation, a tighter erased cell Vt distribution, an increase in memory device endurance and lifetimes due to a decrease in memory cell overerasure and overstress, and a more accurate match of word line erase voltages to the specific non-volatile memory array, the specific region or row being programmed, and any changes in programming characteristics due to device use and wear. In one embodiment of the present invention, the differing word line erase voltages are utilized to compensate for faster and slower erasing word lines. In another embodiment, different word line erase voltages are applied based on physical aspects of the word lines of the array, including, but not limited to, an interlaced array of alternating wide/thin word lines which have higher/lower word line resistances and/or capacitive coupling ratios with the underlying non-volatile memory cells. In embodiments of the present invention, two or more voltage levels can be applied to the word lines of the erase block selected for erasure. In one embodiment of the present invention, the word line erase voltages are selected before beginning erasure based on known fast or slow erasing word lines. What constitutes a fast or slow erasing word line can be selected based on the physical characteristics of the word lines or memory array structure or by a record of memory array data from array testing or by a record of past erase cycles of the erase blocks. In another embodiment, the word line voltages can be iteratively adjusted for each following erase cycle of a block erase operation based on the results of the erase verification. In yet another embodiment of the present invention, the word line voltages are adjusted to compensate for word lines or memory cells that are vulnerable to program disturb by erasing them deeper or more shallow than the rest of the erase block. In a further embodiment, the following erase cycles of an erase operation are repeated with differing word line erase voltage levels on selected word lines that failed verification to erase the memory cells that failed to erase correctly in the previous cycles. It is noted that embodiments of the present invention include all non-volatile memory cell devices and memories that trap charge in an electrically isolated region (such as charge trapping/floating node memory cells) and are not limited to floating gate memory cell arrays or memory devices.

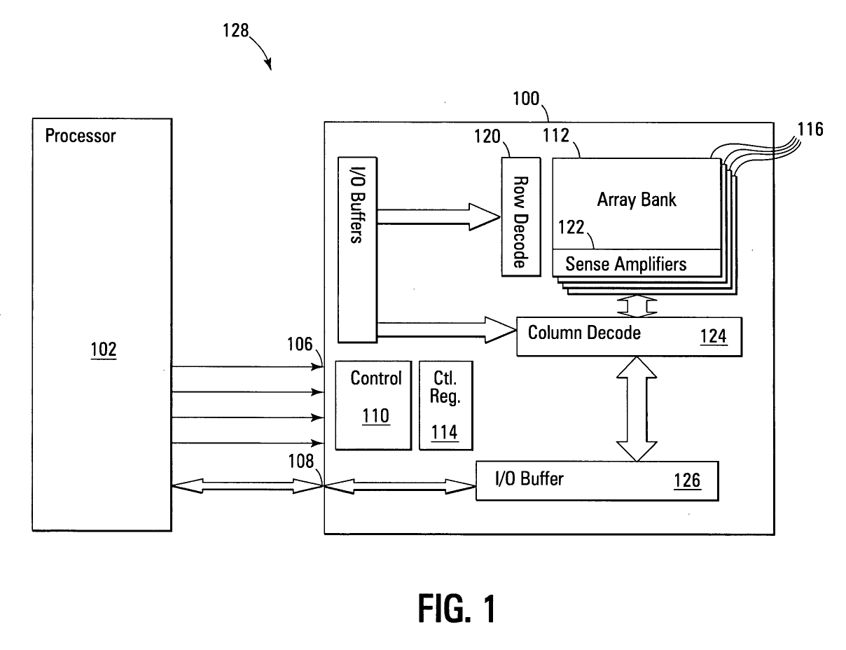

FIG. 1 details a simplified diagram of a system 128 incorporating a non-volatile memory device 100 of an embodiment of the present invention connected to a host 102, which is typically a processing device or memory controller. The non-volatile memory 100, such as a Flash memory device, has a control interface 106 and an address/data interface 108 that are each connected to the processing device 102 to allow memory read and write accesses. It is noted that in alternative embodiments, the address/data interface 108 can be divided into separate interfaces. Internal to the non-volatile memory device a control state machine/control circuit 110 directs the internal operation; managing the non-volatile memory array 112 and updating RAM control registers and erase block management registers 114. The RAM control registers and tables 114 are utilized by the control state machine 110 during operation of the non-volatile memory 100. The non-volatile memory array 112 contains a sequence of memory banks or segments 116, each bank 116 is organized logically into a series of erase blocks (not shown). Memory access addresses are received on the address/data interface 108 of the non-volatile memory 100 and divided into a row and column address portions. On a read access the row address is latched and decoded by row decode circuit 120, which selects and activates a row page (not shown) of memory cells and the other memory cells in their associated strings across a selected memory bank. The bit values encoded in the output of the selected row of memory cells are connected from a local bitline/string (not shown) to a global bitline (not shown) and detected by sense amplifiers 122 associated with the memory bank. The sense amplifiers 122 also typically include a data cache and write data latch circuits (not shown). The column address of the access is latched and decoded by the column decode circuit 124. The output of the column decode circuit selects the desired column data from the sense amplifier outputs and connected to the data buffer 126 for transfer from the memory device through the address/data interface 108. On a write access the row decode circuit 120 selects the row page and column decode circuit selects write sense amplifiers 122. Data values to be written are connected from the data buffer 126 to the data cache and then to the write data latches of the write sense amplifiers 122 selected by the column decode circuit 124 and written to the selected non-volatile memory cells (not shown) of the memory array 112. The written cells are then reselected by the row and column decode circuits 120, 124 and sense amplifiers 122 so that they can be read to verify that the correct values have been programmed into the selected memory cells. It is noted that in one embodiment of the present invention, the column decode 124 may be optionally placed between the memory array 112 and the sense amplifiers 122.

Two common types of non-volatile or Flash memory array architectures are the “NAND” and “NOR” architectures, so called for the resemblance which the basic memory cell configuration of each architecture has to a basic NAND or NOR gate circuit, respectively. In the NOR array architecture, the memory cells of the memory array are arranged in a matrix similar to conventional RAM or ROM. The gates of each non-volatile memory cell of the array matrix are coupled by rows to word select lines (word lines) and their drains are coupled to column bit lines. The source of each memory cell is typically coupled to a common source line. The NOR architecture floating gate or floating node/charge trapping memory array is accessed by a row decoder activating a row of memory cells by selecting the word line coupled to their gates. The row of selected memory cells then place their stored data values on the column bit lines by flowing a differing current from the coupled source line to the coupled column bit lines depending on their programmed states. A column page of bit lines is selected and sensed, and individual data words are selected from the sensed data words from the column page and communicated from the memory.

A NAND memory array architecture also arranges its array of non-volatile memory cells in a matrix such that the gates of each memory cell of the array are coupled by rows to word lines. However each memory cell is not directly coupled to a source line and a column bit line. Instead, the memory cells of the array are arranged together in strings, typically of 8, 16, 32, or more each, where the memory cells in the string are coupled together in series, source to drain, between a common source line and a column bit line. This allows a NAND array architecture to have a higher memory cell density than a comparable NOR array, but with the cost of a generally slower access rate and programming complexity.

A NAND architecture floating gate or floating node memory array is accessed by a row decoder activating a row of memory cells by selecting the word select line coupled to their gates. In addition, the word lines coupled to the gates of the unselected memory cells of each string are also driven. However, the unselected memory cells of each string are typically driven by a higher gate voltage so as to operate them as pass transistors and allowing them to pass current in a manner that is unrestricted by their stored data values. Current then flows from the source line to the column bit line through each floating gate/node memory cell of the series coupled string, restricted only by the memory cells of each string that are selected to be read. This places the current encoded stored data values of the row of selected memory cells on the column bit lines. A column page of bit lines is selected and sensed, and then individual data words are selected from the sensed data words from the column page and communicated from the memory device.

It is noted that embodiments of the present invention are not limited to NAND or NOR architecture memory arrays or memory devices and can apply to other block erasing memory array architectures and memory devices, including, but not limited to AND and virtual ground architecture memory arrays and memory devices.

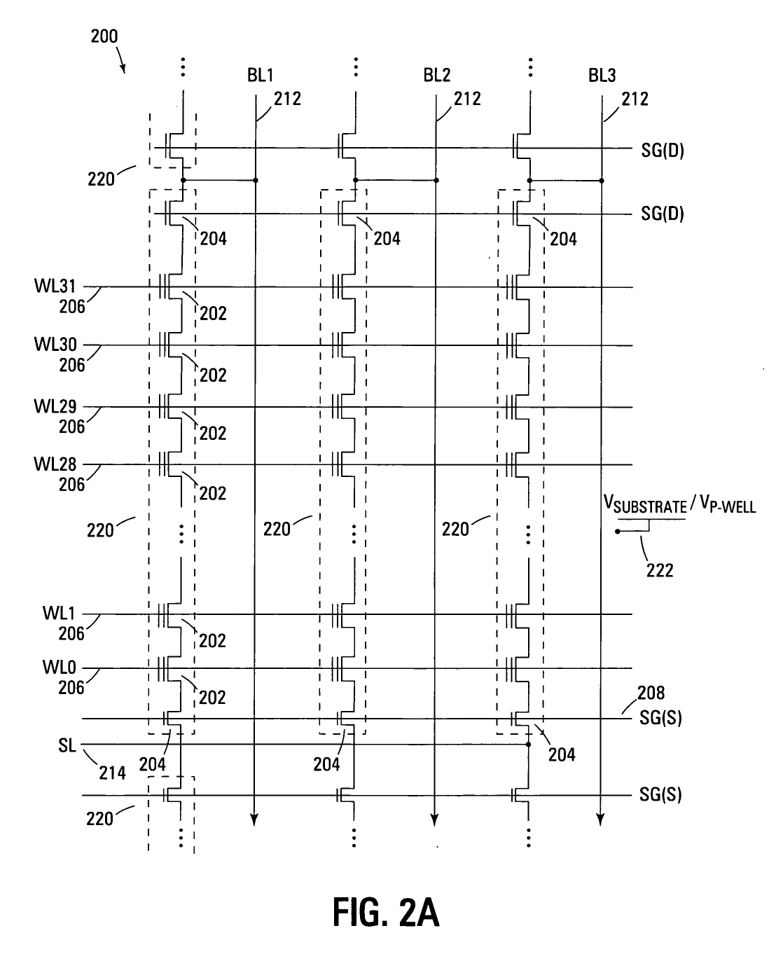

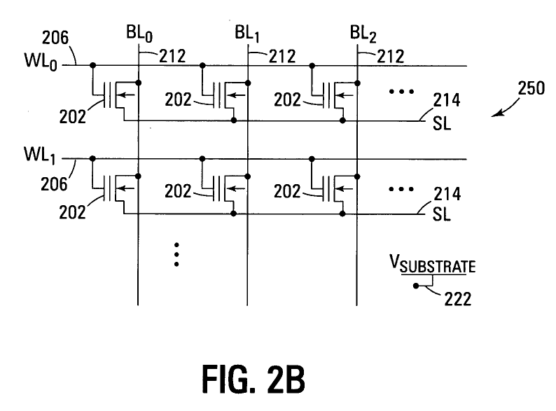

FIGS. 2A and 2B show schematics of a simplified NOR and NAND architecture floating node or trapping layer memory array 200, 250 of a Flash memory device of an embodiment of the present invention. It is noted that the memory arrays 200, 250 of FIGS. 2A and 2B are for illustrative purposes and should not be taken as limiting and that other memory array embodiments of the present invention are possible and will be apparent to those skilled in the art with the benefit of the present disclosure.

In FIG. 2A, a series of NAND memory strings 220 are arranged in an array 200 and coupled to bit lines 212 and source lines 214. In each NAND memory string 220, a series of floating gate or floating node memory cells 202 of embodiments of the present invention are coupled together source to drain to form the NAND string 220 (typically having 8, 16, 32, or more cells). As described above, each floating gate/node memory cell FET 202 has a gate-insulator stack formed over the channel region. To further enable operation, in one embodiment of the present invention, each NAND architecture memory string 220 of the memory is formed in an isolation trench, allowing the substrate of each isolation trench to be individually biased for programming and erasure. The word lines 206 couple across the NAND strings 220, coupling the control gates of adjacent memory cells 202 enabling a single memory cell 202 in each memory string 220 to be selected. In each NAND memory string 220, impurity (N+typically) doped regions are formed between each gate insulator stack to form the source and drain regions of the adjacent memory cells 202, which additionally operate as connectors to couple the cells of the NAND string 220 together. In one embodiment of the present invention, the N+doped regions are omitted and a single channel region is formed under the NAND memory string 220, coupling the individual memory cells 202. Each NAND memory string 220 is coupled to select gates 204 that are formed at either end of each NAND string 220 and selectively couple opposite ends of each NAND string 220 to a bit line 212 and a source line 214. The select gates 204 are each coupled to gate select lines, select gate drain {SG(D)} 210 and select gate source {SG(S)} 208, that control the coupling of the NAND strings to the bit lines 212 and source lines 214, respectively, through the select gates 204. In FIG. 2A, the substrate connection 222 is shown coupled to each NAND string 220, allowing the memory cells 202 of each NAND string 220 to be biased for erasure.

FIG. 2B details a simplified NOR floating gate/node memory array 250 of a Flash memory device embodiment of the present invention. In FIG. 2B, floating gate/node memory cells 202 are coupled together in a NOR architecture memory array having bit lines 212, source lines 214, word lines 206, and substrate connection 222. Each floating gate memory cell 202 has a floating gate or floating node/charge trapping field effect transistor (FET) comprising a gate-insulator stack formed between drain and source regions that are coupled to a bit line 212 and a source line 214, respectively.

Common programming technique for Flash memories programs a bit or row (commonly referred to as a page) of the memory by applying a programming voltage or series of programming voltage pulses to the control gates of the selected memory cells and programming or inhibiting the selected memory cells to either program (set at logical “0” by the injection of charge to the floating gate or floating node of a memory cell) or inhibit (not program, usually intended to leave the cell erased and set at logical “1”) by coupling their channels to either a program or inhibit voltage.

As stated above, block erasure for Flash memories typically pre-programs any remaining un-programmed memory cells of the erase block. This pre-programming is done in order to reduce the chances of the cells from being overerased and going into a depletion mode. If not pre-programmed, as the cells of an erase block get erased it would be possible that they could get erased to the point where they go into depletion mode threshold voltage and conduct current even when those cells have a control gate voltage of 0V. This can affect the reading of all other cells in their respective columns. By pre-programming the memory, the cells start from a known, uniform programmed state and are therefore less likely to go into an overerased depletion state.

The erase operation is then conducted to erase the cells to at least a minimum threshold voltage level by applying an erase voltage to the substrate connection (or in some cases the channel) of the memory cells while grounding (applying a lower voltage than the substrate erase voltage) their control gates/word lines to apply a field across the gate-insulator stack to erase the memory cell. This applied erase field removes the charge stored in the floating gates or floating nodes and erases the memory cells (typically placing them in an erased state and setting their data values to a logical “1”). It is noted that a block erase operation differs from what is referred to as a “page erase” operation, where only a single page of the memory array is erased. In a page erase operation, the erase voltage is applied to the substrate, but only a single selected word line is grounded, while the others are allowed to float or are coupled to the substrate erase voltage, applying an erase field across only the non-volatile memory cells coupled to the selected word line to erase their stored data values and retaining the data values of the other memory cells of the array or block.

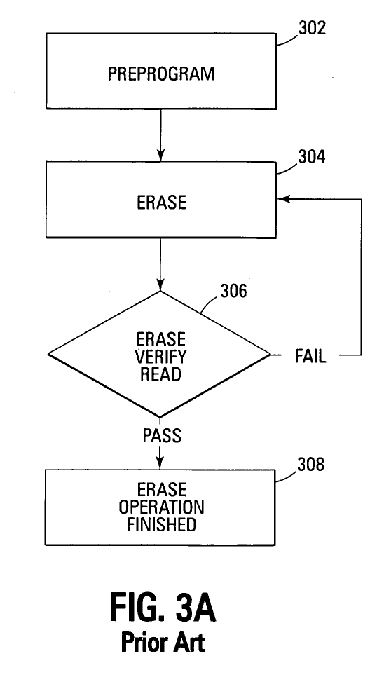

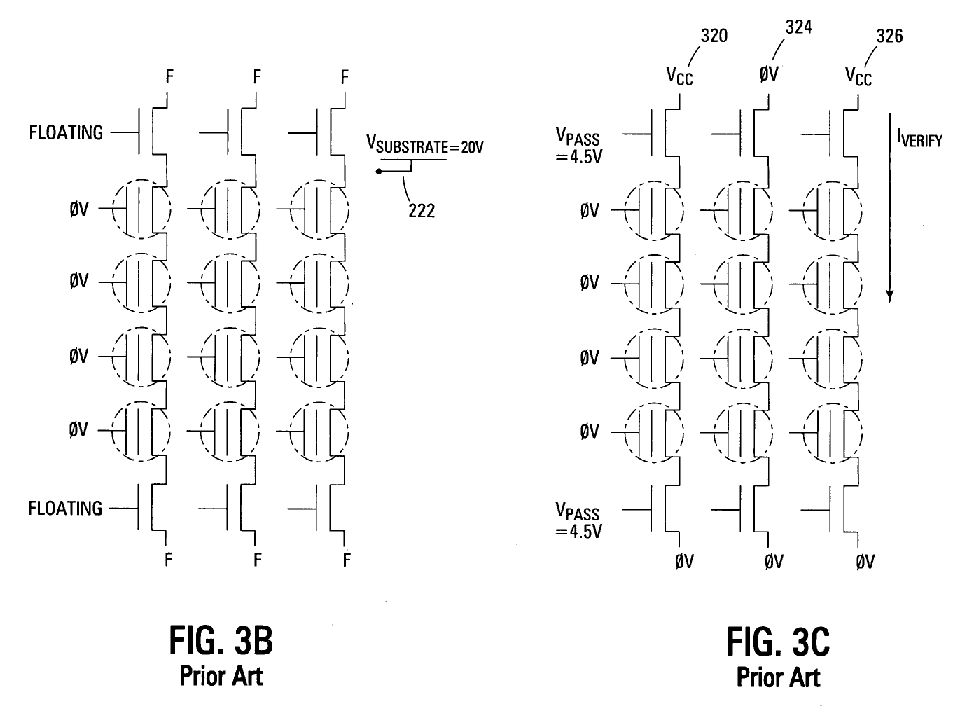

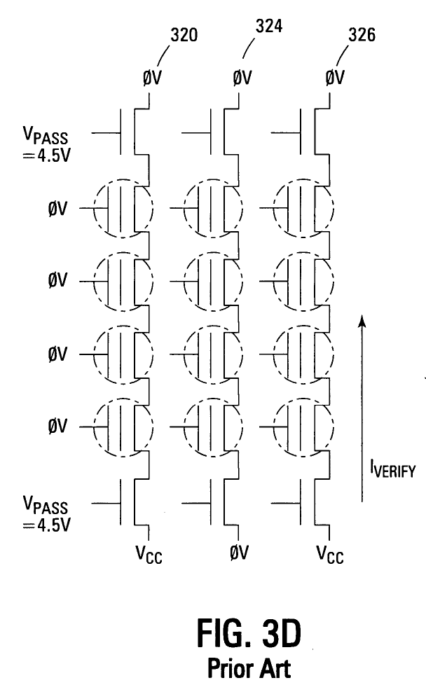

FIG. 3A illustrates a flowchart of a typical prior art erase operation for a block of Flash memory. The memory block is first pre-programmed 302 before an erase operation is performed. The memory block is then erased 304 by applying an erase voltage across the gate-insulator stacks of the memory cells. An erase verify read is then performed 306. If the verify operation fails and one or more memory cells of the erase block still read as being programmed, the erase operation is performed again 304. If the erase block passes verification, the erase operation has been successfully completed 308.

FIG. 3B illustrates a simplified schematic diagram of a Flash memory block undergoing a typical prior art erase operation. The drain and source connections of the bit lines are all typically left floating (F) as are the select gate drain transistors and the select gate source transistors. The word lines of the block to be erased are at ground potential. The dotted lines indicate the memory cells that are selected during this operation.

The erase verify operation is performed in order to determine the success of the erase operation on each cell of the memory block. A simplified schematic diagram of a flash memory block undergoing a typical prior art erase verify operation is illustrated in FIG. 3C. The erase verify operation comprises, at least in part, comparing each cell's erase current to a sense amplifier reference current level. During this operation, all of the word lines and source lines of the block are held at 0V while the selected bit lines 320, 322 are biased at V_{CC} (or a supply voltage level). A 0V pulse is applied to any unselected bit lines 324. The select gate drain and source transistors are held at a pass voltage, such as 4.5V, that is typically referred to in the art as Vₚₐₛₛ. A reverse current flow erase verify operation is illustrated in FIG. 3D, in which the bit lines are held at 0V and the source lines of the selected memory cell strings 320, 322 are biased at Vcc. It is noted that other erase verify operations are possible and known to those skilled in the art.

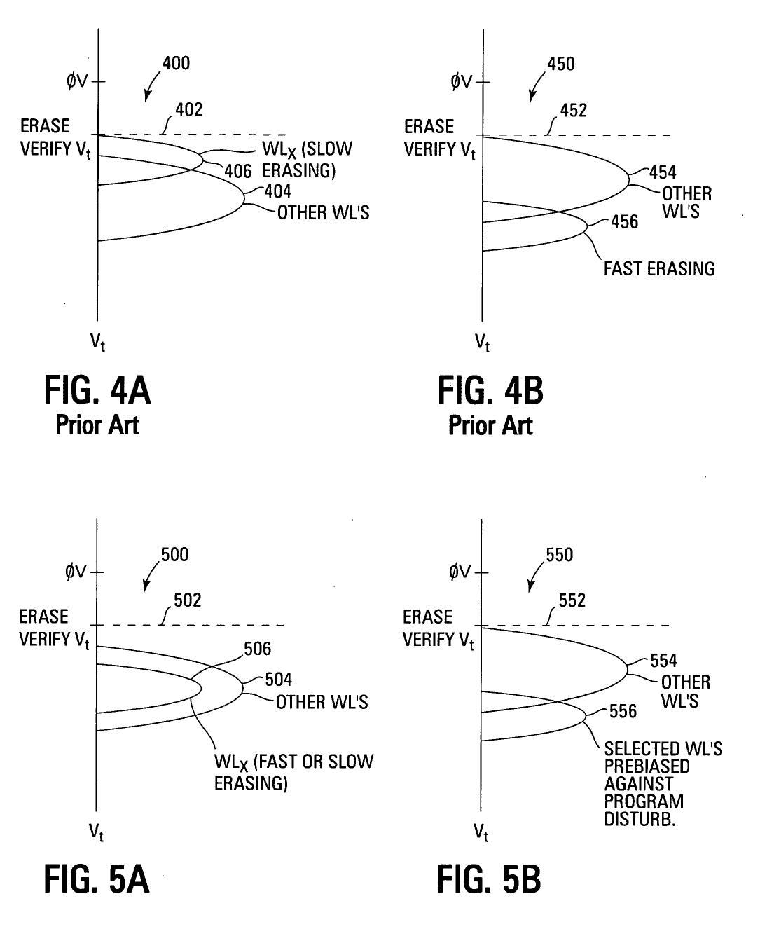

Unfortunately, as stated above, this erasure of the memory cells of an erase block is generally not uniform across each row of the memory array. This non-uniform erasure and removal of carriers from the floating gates/nodes of the memory cells leads to a distribution of shifted threshold voltages in the erased cells, as detailed in FIGS. 4A and 4B. As stated above, for a memory cell to be read as having been erased it must have shifted its threshold voltage below that of the erase cell threshold voltage limit 402, 406. However, as also stated above, due to differences in the word lines, given word lines in an erase block can have faster or slower erase characteristics. This is due to issues that can include, but are not limited to, different word line resistance, differing word line designs/shapes, the word line physical placement in the memory array, device wear levels (memory cell write fatigue), manufacturing process variations, and the word line coupling to the memory cells and other adjacent elements and word lines of the memory array. Because of this, the threshold voltage distribution of the erased memory cells after an erase cycle are skewed with the slower erasing word lines potentially getting undererased (possibly causing additional erase and verify cycles), and faster erasing word lines being potentially overerased and overstressed (decreasing the lifespan of the affected memory cells and the endurance of the erase block).

In FIG. 4A, the distribution 400 of threshold voltages (Vt) of floating gate or floating node/charge trapping memory cells after a prior art erasure operation of an erase block having one or more slow erasing word lines is shown. As shown in FIG. 4A, the main distribution of threshold voltages 404 of the normal or fast erasing word lines can be shifted down in order to lower the threshold voltage of the memory cells associated with the slower erasing word lines 406 enough for them to be below the minimum threshold voltage 402, unintentionally further erasing the memory cells associated with the normal and fast erasing word lines, increasing their stress and possibly inducing premature failure. In FIG. 4B, the distribution 450 of threshold voltages (Vt) of floating gate memory cells after a prior art erasure operation of an erase block having one or more fast erasing word lines is shown. As shown in FIG. 4B, the distribution of threshold voltages 456 of the fast erasing word lines can be pushed down, unintentionally further erasing these memory cells into depletion mode and increasing their stress, in order to lower the threshold voltage of the main distribution of normal or slow erasing word lines 454 enough for them to be below the minimum threshold voltage 452.

Embodiments of the present invention utilize an improved erasure method to provide for an overall faster erase operation and provide better matching of the erase operation to the specific word line erasure speed of the non-volatile erase block or memory device. In embodiments of the present invention, the word line voltage applied to the word lines while the substrate or channel is biased at an erase voltage level during erasure are pre-selected in relation to the known erase speed of the individual word lines. In another embodiment of the present invention, the word line voltages of successive erase cycles of a block erase operation are selected according to the results of the previous erase verification, allowing the erase cycle to be iteratively adjusted to the individual erase speeds of the word lines/rows of the erase block. This allows for a faster erase operation through few iterations and lowers memory cell erase stress, allowing for a more accurate match of the subsequent word line erase voltages to the specific word lines of the non-volatile memory device and any changes in programming characteristics due to device use and wear. In yet another embodiment, different word line erase voltages are applied to non-uniform memory arrays based on physical aspects of the word lines of the array, including, but not limited to, an interlaced array of alternating wide/thin cross section word lines which have higher/lower word line resistances and/or capacitive coupling ratios with the underlying non-volatile memory cells or first or last word line differences of a memory string/block/array segment. In embodiments of the present invention, two or more voltage levels can be applied to the word lines of the erase block selected for erasure. In yet a further embodiment of the present invention, selected word lines known to be subject to read or program disturb because of placement or operational characteristics are biased at an increased erase voltage level during erasure to intentionally erase them deeper than other word lines of the memory array or erase block in order to provide them with an increased margin of immunity from disturb. It is noted that the erase method of embodiments of the present invention can be utilized in NAND Flash memory devices, NOR Flash memory devices, and any non-volatile memory device that bulk erases data in erase blocks or in some other parallel fashion.

FIG. 5A illustrates a distribution 500 of threshold voltages (Vt) of floating gate/node memory cells after an erasure operation of an embodiment of the present invention. As shown in FIG. 5A, the main distribution of threshold voltages 504 of the normal erasing word lines and that of the fast and/or slow erasing word lines 506 are overlapped by the application of differing word line voltage in embodiments of the present invention. This helps avoid the overerasure and stressing of fast erasing word lines and unnecessary additional erase cycles to guarantee the erasure of slow erasing word lines past the minimum threshold voltage level 502. In FIG. 5B, the distribution 550 of threshold voltages (Vt) of floating gate/node memory cells after an erasure operation of an erase block having one or more word lines that have been selected for deeper erasure 556 to increase their disturb immunity is shown. As shown in FIG. 4B, the distribution of threshold voltages 554 of the selected word lines are pushed down by lowering their applied word line voltages, increasing the applied erase field and intentionally erasing their memory cells deeper into depletion mode in order to lower their threshold voltage below that of the main distribution 554 of word lines that has passed the minimum threshold voltage 552 and thereby provide a greater immunity to program disturb on these selected word lines 556.

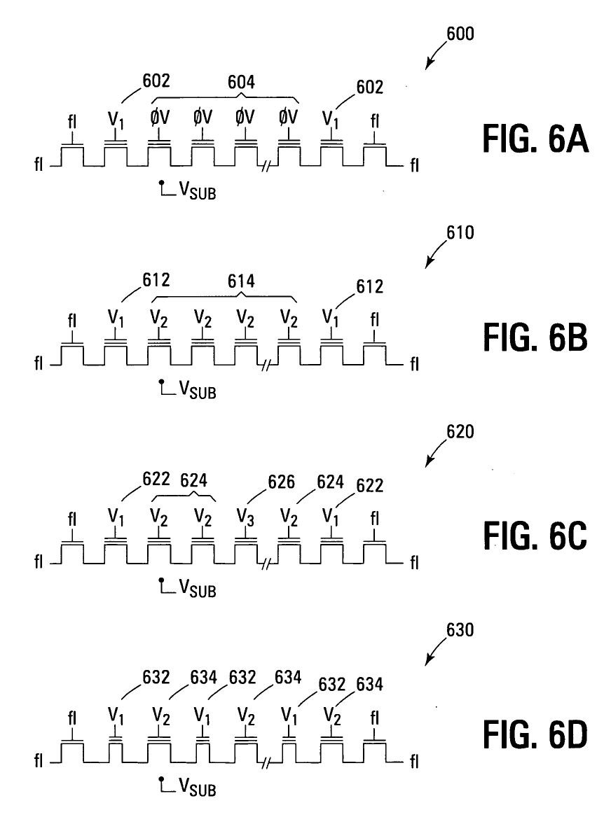

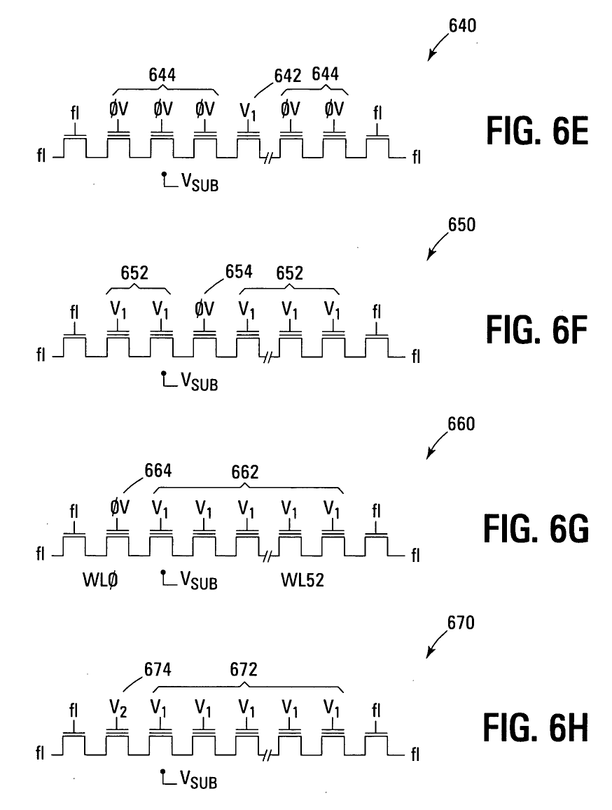

FIGS. 6A-6H detail simplified schematics of NAND memory cell strings of a NAND memory array undergoing various erase operations of embodiments of the present invention. It is noted that the NAND memory cell strings of FIGS. 6A-6H are for illustrative purposes and should not be taken as limiting and that similar concepts are applicable to other memory array embodiments of the present invention, such as, but not limited to, NOR, AND, and virtual ground memory arrays, which will be apparent to those skilled in the art with the benefit of the present disclosure. It is also noted that, in embodiments of the present invention, an entire block or array of non-volatile memory cells is being erased and erase voltages are being applied to all word lines of the block/array, as opposed to a page erase operation, where an erasing word line voltage is applied to a single word line to erase a page of the memory array and the other word lines are allowed to float or are coupled to the substrate erase voltage so as to preserve the contents of their coupled memory cells.

In FIG. 6A, a simplified schematic diagram of a NAND memory cell string 600 of a Flash memory block undergoing an erase operation of an embodiment of the present invention is shown. The drain and source connections of the bit lines are typically all left floating (F) as are the select gate drain transistors and the select gate source transistors and an erase voltage is applied to the substrate connection (Vsub) or channel regions of the memory cells. The word lines of the memory string/block to be erased are at ground potential 604, with the exception of the first and last word lines to which the word line voltage V₁ has been applied 602. This differing word line voltage V₁ 602 allows the first and last word lines to be corrected for faster erasure than the other word lines of the memory string, or, alternatively, allows them to be erased to a deeper or shallower Vt than the other word lines. In FIG. 6B, the word lines of the memory string/block 620 to be erased are biased at two differing voltages, V₁ 612 and V₂ 614, with V₁ 612 again being applied to the first and last word lines of the memory string 610. This differing word line voltages V₁ 612 and V₂ 614 allow the first and last word lines to be corrected for faster or slower erasure than the other word lines of the memory string, in addition to allowing them to be erased to a deeper or shallower Vt than the other word lines. In FIG. 6C, the word lines of the memory string/block 620 to be erased are biased at three differing voltages, V₁ 622, V₂ 624, and V₃ 626. It is noted that word line voltages in a preferred embodiment are equal to or smaller than Vcc, such as, but not limited to, 0V, 0.5V, and 1V. It is also noted, however, that other voltages are possible, both positive and negative, and will be apparent to those skilled in the art with the benefit of the present disclosure. In FIG. 6D, the word lines of the memory string/block 630 to be erased are biased at two differing voltages, V₁ 632 and V₂ 634 in an alternating pattern, such as could be utilized for an array with an alternating word line geometry (as shown by the alternating memory cell gate-stack and word line widths in FIG. 6D), resistances, or coupling ratios to allow for a more uniform erased memory cell threshold voltage distribution. In FIG. 6E, the word lines of the memory string/block 640 to be erased are biased at ground 644 and V₁ 642, such as could be utilized for an array with a fast erasing word line, with V₁ 642 being applied to the fast erasing word line. In FIG. 6F, the word lines of the memory string/block 650 to be erased are biased at ground 654 and V₁ 652, such as could be utilized for an array with a slow erasing word line, with ground 654 being applied to the slower erasing word line. In FIG. 6G, the word lines of the memory string/block 660 to be erased are biased at ground 664 and V₁ 662, such as could be utilized to pre-bias the memory cells of the first word line (WL0) to a deeper erased threshold voltage level for increased resistance to read or program disturb, with ground 664 being applied to WL0. In FIG. 6H, the word lines of the memory string/block 670 to be erased are biased at V₁ 662 and V₂ 664, such as could be utilized to pre-bias the memory cells of the first word line (WL0) to a shallower or deeper erased threshold voltage level than the other word lines of the memory string 670, dependant on the relative levels of V₁ 662 and V₂ 664.

As will be apparent to one skilled in the art, differing erase word line voltages and patterns can be set in embodiments of the present invention to compensate for a variety of different word line erase speeds or to bias different word lines to deeper or shallower erased threshold voltages, as desired by the memory designer or end user or intended memory application. It is also noted that elevated voltages applied to the word lines have an additional benefit of increased protection for the global word line driver and/or pass transistors by allowing for a lower erase voltage differential to be dropped across them when an elevated local word line erase voltage is applied during an erase operation.

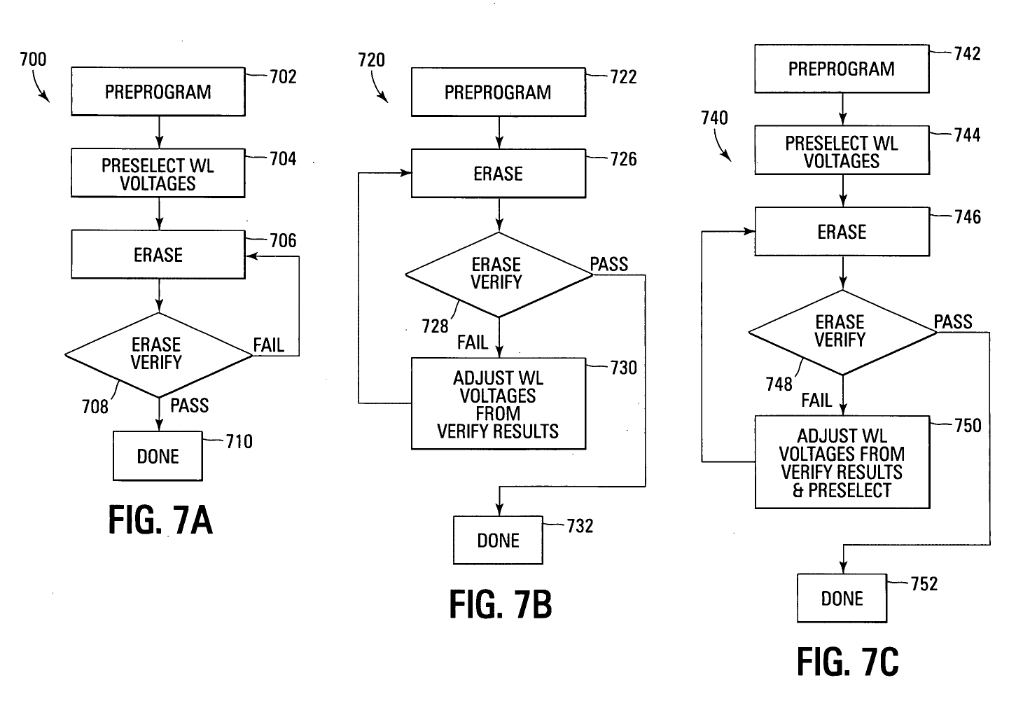

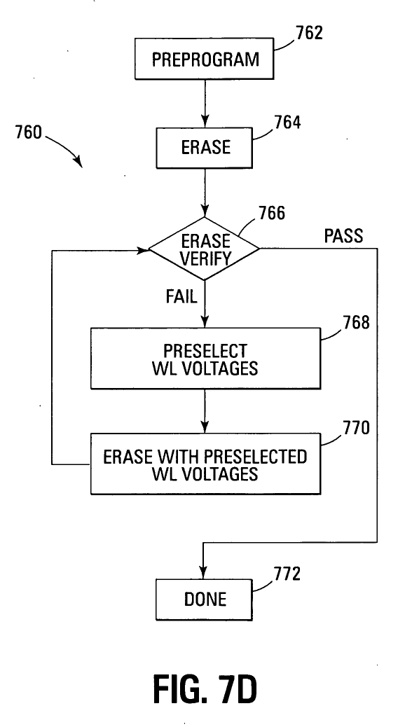

FIGS. 7A-7D detail simplified flowcharts of erase operations for a block of Flash memory erase operations for embodiments of the present invention. It is noted that the erase operations of FIGS. 7A-7D are for illustrative purposes and should not be taken as limiting.

FIG. 7A illustrates a flowchart 700 of an erase operation for an erase block of an embodiment of the present invention utilizing word line voltages that are pre-set before start of the erase cycle based on historical data that has been kept on past erasure of the individual erase block or array or design/operational criteria. The remaining unprogrammed memory cells of the erase block are first pre-programmed 702 before the erase operation is performed. The word line voltages are pre-selected 704 based on the selected word line erase criteria for the erase block, such as, a first voltage for word lines deemed to be fast (thereby lowering the applied erase field on the coupled memory cells), and a second, lower voltage, for word lines deemed to be slow (thereby increasing the applied erase field on the coupled memory cells). The memory block is then erased 706 by applying an erase voltage to the substrate connection or to the memory cell channels and thus asserting an erase field across the gate-insulator stacks of the memory cells to erase them. An erase verify read is then performed 708 to confirm the proper erasure of the memory cells of the erase block. If the verify operation fails and one or more memory cells of the erase block still read as being programmed, the erase operation is performed again 706. If the erase block passes verification, the erase operation successfully completes 710.

FIG. 7B illustrates a flowchart 720 of an erase operation for an erase block of another embodiment of the present invention utilizing word line voltages that are iteratively adjusted during the erase cycle based on the results of the erase verify operation and any identified fast or slow erasing word lines. In the erase operation, the remaining unprogrammed memory cells of the erase block are first pre-programmed 722 before the main erase operation is performed. The memory block is then erased 726 for the first erase operation cycle by applying an erase voltage to the substrate connection or to the memory cell channels and a uniform word line erase voltage to the word lines (typically ground or 0V) and thus asserting an erase field across the gate-insulator stacks of the memory cells to erase them. An erase verify read is then performed 728 to confirm the proper erasure of the memory cells of the erase block. If the verify operation fails and one or more memory cells of the erase block still read as being programmed, the word line voltages are adjusted during the erase cycle based on the results of the erase verify operation 730 and erase operation is performed again 726. This adjustment can include, but is not limited to, increasing the word line voltage for word lines deemed to be fast, and/or decreasing the word line voltage for word lines deemed to be slow. If the erase block passes verification, the erase operation successfully completes 732. It is noted that in one embodiment of the present invention the erase operation 720 utilizes a slower, but more accurate, normal read operation of the erase block instead of a standard erase verification operation on the memory cells to get a more accurate picture of the erase state of the erase block.

FIG. 7C illustrates a flowchart 740 of an erase operation for an erase block of another embodiment of the present invention utilizing word line voltages that are both pre-selected before the erase cycle begins based on design or historical data and then are iteratively adjusted during the erase cycle based on the results of the erase verify operation and any identified fast or slow erasing word lines. In the erase operation, the remaining unprogrammed memory cells of the erase block are first pre-programmed 742 before the main erase operation is performed. The word line voltages are pre-selected 744 based on historical data that has been kept on past erasure of the individual erase block or array or design/operational criteria of the erase block or memory array. The memory block is then erased 746 by applying an erase voltage to the substrate connection or to the memory cell channels and thus asserting an erase field across the gate-insulator stacks of the memory cells to erase them. An erase verify read is then performed 748 to confirm the proper erasure of the memory cells of the erase block. If the verify operation fails and one or more memory cells of the erase block still read as being programmed, the word line voltages are adjusted during the erase cycle based on the results of the erase verify operation 750 and erase operation is performed again 746. If the erase block passes verification, the erase operation successfully completes 752.

FIG. 7D illustrates a flowchart 760 of an erase operation for an erase block of yet another embodiment of the present invention where the non-volatile memory cells are erased by an initial erase cycle and then are iteratively adjusted based on the results of the erase verify operation and any identified fast or slow erasing word lines. In the erase operation, the remaining unprogrammed memory cells of the erase block are first pre-programmed 762 before the main erase operation is performed. An initial erase cycle operation is then performed 764 utilizing word line voltages that are uniform (such as 0V). An erase verify read is then performed 766 to confirm the proper erasure of the memory cells of the erase block. If the verify operation fails and one or more memory cells of the erase block still read as being programmed, the word line voltages are adjusted utilizing word line voltages that are selected based on historical data that has been kept on past erasure of the individual erase block or array or design/operational criteria 768 and another erase cycle utilizing these selected word line voltages is performed 770. The erase operation then loops and the erase verify read is performed again 766 to confirm the proper erasure of the memory cells of the erase block. If the erase block passes verification, the erase operation successfully completes 772.

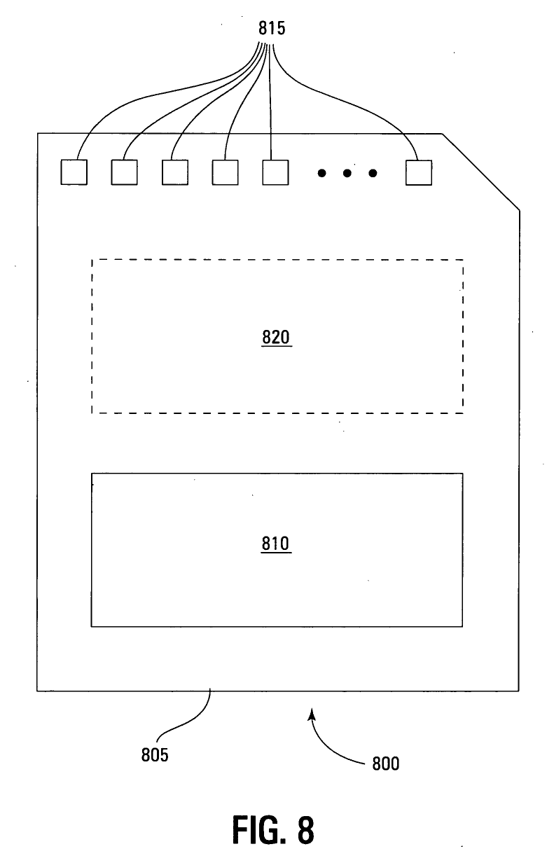

FIG. 8 is an illustration of an exemplary memory module 800. Memory module 800 is illustrated as a memory card, although the concepts discussed with reference to memory module 800 are applicable to other types of removable or portable memory, e.g., USB flash drives, and are intended to be within the scope of “memory module” as used herein. In addition, although one example form factor is depicted in FIG. 8, these concepts are applicable to other form factors as well.

In some embodiments, memory module 800 will include a housing 805 (as depicted) to enclose one or more memory devices 810, though such a housing is not essential to all devices or device applications. At least one memory device 810 is a non-volatile memory including circuits of or adapted to perform elements of methods of the present invention. Where present, the housing 805 includes one or more contacts 815 for communication with a host device. Examples of host devices include digital cameras, digital recording and playback devices, PDAs, personal computers, memory card readers, interface hubs and the like. For some embodiments, the contacts 815 are in the form of a standardized interface. For example, with a USB flash drive, the contacts 815 might be in the form of a USB Type-A male connector. For some embodiments, the contacts 815 are in the form of a semi-proprietary interface, such as might be found on CompactFlash™ memory cards licensed by SanDisk Corporation, Memory Stick™ memory cards licensed by Sony Corporation, SD Secure Digital™ memory cards licensed by Toshiba Corporation and the like. In general, however, contacts 815 provide an interface for passing control, address and/or data signals between the memory module 800 and a host having compatible receptors for the contacts 815.

The memory module 800 may optionally include additional circuitry 820 which may be one or more integrated circuits and/or discrete components. For some embodiments, the additional circuitry 820 may include a memory controller for controlling access across multiple memory devices 810 and/or for providing a translation layer between an external host and a memory device 810. For example, there may not be a one-to-one correspondence between the number of contacts 815 and a number of I/O connections to the one or more memory devices 810. Thus, a memory controller could selectively couple an I/O connection (not shown in FIG. 8) of a memory device 810 to receive the appropriate signal at the appropriate I/O connection at the appropriate time or to provide the appropriate signal at the appropriate contact 815 at the appropriate time. Similarly, the communication protocol between a host and the memory module 800 may be different than what is required for access of a memory device 810. A memory controller could then translate the command sequences received from a host into the appropriate command sequences to achieve the desired access to the memory device 810. Such translation may further include changes in signal voltage levels in addition to command sequences.

The additional circuitry 820 may further include functionality unrelated to control of a memory device 810 such as logic functions as might be performed by an ASIC (application specific integrated circuit). Also, the additional circuitry 820 may include circuitry to restrict read or write access to the memory module 800, such as password protection, biometrics or the like. The additional circuitry 820 may include circuitry to indicate a status of the memory module 800. For example, the additional circuitry 820 may include functionality to determine whether power is being supplied to the memory module 800 and whether the memory module 800 is currently being accessed, and to display an indication of its status, such as a solid light while powered and a flashing light while being accessed. The additional circuitry 820 may further include passive devices, such as decoupling capacitors to help regulate power requirements within the memory module 800.

It is noted that other erase operations and voltage levels for non-volatile memory device and array embodiments of the present invention are possible and will be apparent for those skilled in the art with the benefit of this disclosure.

### CONCLUSION

A non-volatile memory device and programming process has been described that erases blocks of non-volatile memory cells by the application of differing word line erase voltages to selected word lines during an erase cycle. This facilitates a faster on average erase operation, a tighter erased cell Vt distribution, an increase in memory device endurance and lifetimes due to a decrease in memory cell overerasure and overstress, and a more accurate match of word line voltages to the specific non-volatile memory array, the specific region or row being programmed, and any changes in programming characteristics due to device use and wear. In one embodiment of the present invention, the differing word line erase voltages are utilized to compensate for faster and slower erasing word lines. In another embodiment, different word line erase voltages are applied based on physical aspects of the word lines of the array, such as, but not limited to, an interlaced array of alternating wide/thin word lines which have higher/lower word line resistances and/or capacitive coupling ratios with the underlying non-volatile memory cells. In one embodiment of the present invention, the word line erase voltages are selected before beginning erasure based on known fast or slow erasing word lines. In another embodiment, the word line voltages can be iteratively adjusted for each following erase cycle of a block erase operation based on the results of the erase verification. In yet another embodiment of the present invention, the word line voltages are adjusted to compensate word lines or memory cells that are vulnerable to program disturb by erasing them more deeply than the rest of the erase block. In a further embodiment, the following erase cycles of an erase operation are repeated with differing word line erase voltage levels on selected word lines that failed verification to erase the memory cells that failed to erase correctly in the previous cycles.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A method of erasing memory cells, comprising:
applying two or more word line erase voltages to a plurality of word lines, each word line coupled to one or more non-volatile memory cells of a block of memory cells of a non-volatile memory array having a plurality of non-volatile memory cells; and
applying an erase voltage to a substrate connection of the non-volatile memory cells coupled to the plurality of word lines to erase the block of memory cells.

2. The method of claim 1, wherein applying two or more word line erase voltages to a plurality of word lines of a block of memory cells further comprises applying two or more word line erase voltages to a plurality of word lines of a block of memory cells, where the word line erase voltages are selected based on physical characteristics of the plurality of word lines.

3. The method of claim 2, wherein physical characteristics of the plurality of word lines are one of the erasure speed of each of the plurality of word lines, the resistance of each of the plurality of word lines, the coupling ratio of each of the plurality of word lines, and the cross-sectional area of each of the plurality of word lines.

4. The method of claim 1, wherein applying two or more word line erase voltages to a plurality of word lines of a block of memory cells further comprises applying two or more word line erase voltages to a plurality of word lines of a block of memory cells, where the word line erase voltages are selected based on an alternating pattern of wide and thin widths of the plurality of word lines in the memory array.

5. The method of claim 1, wherein applying two or more word line erase voltages to a plurality of word lines of a block of memory cells further comprises applying two or more word line erase voltages to a plurality of word lines of a block of memory cells, where the word line erase voltages are selected based on one of the erasure history of each of the plurality of word lines, and the placement of each of the plurality of word lines in the memory array.

6. The method of claim 1, wherein applying two or more word line erase voltages to a plurality of word lines of a block of memory cells further comprises applying two or more word line erase voltages to a plurality of word lines of a block of memory cells, where the word line erase voltages are selected to erase the non-volatile memory cells of one or more word lines deeper or shallower than the memory cells of other word lines.

7. The method of claim 1, further comprising:
erase verifying the non-volatile memory cells of the block of memory cells coupled to the plurality of word lines; and
adjusting the two or more word line erase voltages applied to the plurality of word lines of the block of memory cells if one or more non-volatile memory cells fail erase verification to compensate one or more word lines that are erasing at a differing speed than other word lines of the plurality of word lines.

8. The method of claim 1, further comprising pre-programming the non-volatile memory cells of the block of memory cells.

9. The method of claim 1, wherein the block of non-volatile memory cells is an erase block.

10. The method of claim 1, wherein the non-volatile memory array is one of a NAND architecture memory array and a NOR architecture memory array.

11. The method of claim 1, wherein applying an erase voltage to a substrate connection of the non-volatile memory cells coupled to the plurality of word lines to erase the block of memory cells further comprises applying an erase voltage to a channel of the non-volatile memory cells coupled to the plurality of word lines to erase the block of memory cells.

12. The method of claim 1, wherein applying two or more word line erase voltages to a plurality of word lines of a block of memory cells further comprises applying two or more word line erase voltages to a plurality of word lines of a block of memory cells, where the word line erase voltages are selected to be less than or equal to a Vcc voltage.

13. A method of operating a non-volatile memory device, comprising:
erasing a selected block of non-volatile memory cells;
erase verifying the block of non-volatile memory cells; and
adjusting the voltages applied to one or more word lines of the block of non-volatile memory cells if the block fails erase verification to compensate one or more word lines that are erasing at a differing speed than the other word lines of the block.

14. The method of claim 13, further comprising pre-programming the memory cells of the selected block of non-volatile memory cells before erasing.

15. The method of claim 13, wherein the one or more word lines erasing at a differing speed are one of a fast erasing word line and a slow erasing word line.

16. The method of claim 13, wherein the erase verification is a normal read operation of the block of non-volatile memory cells.

17. The method of claim 13, wherein the non-volatile memory device is one of a NAND architecture memory device and a NOR architecture memory device.

18. The method of claim 13, further comprising pre-selecting two or more word line voltages of the selected block of non-volatile memory cells before erasing.

19. The method of claim 13, further comprising initially erasing the selected block of non-volatile memory cells with an initial erase cycle word line voltage.

20. The method of claim 13, wherein the voltages applied to one or more word lines of the block of non-volatile memory cells are selected to be less than or equal to a supply voltage.

21. A method of operating a non-volatile memory device, comprising:
selecting two or more word line voltages for a plurality of word lines of an erase block that has been selected for erasure; and
erasing the selected erase block of non-volatile memory cells.

22. The method of claim 21, further comprising:
erase verifying the block of non-volatile memory cells; and
adjusting the voltages applied to one or more word lines of the erase block if the block fails erase verification.

23. The method of claim 22, wherein adjusting the voltages applied to one or more word lines further comprises adjusting the voltages applied to one or more fast erasing word lines or one or more slow erasing word lines.

24. The method of claim 21, further comprising pre-programming the memory cells of the erase block before erasing.

25. The method of claim 21, wherein the non-volatile memory device is one of a NAND architecture memory device and a NOR architecture memory device.

26. The method of claim 21, wherein selecting two or more word line voltages for a plurality of word lines of an erase block that has been selected for erasure further comprises selecting two or more word line voltages for a plurality of word lines based on one of physical characteristics of the word lines, a record of memory array characteristic data from testing of the memory array, and a record of past erase cycles of the erase blocks or word lines.

27. The method of claim 21, wherein selecting two or more word line voltages for a plurality of word lines of an erase block that has been selected for erasure further comprises selecting two or more word line voltages for a plurality of word lines to compensate word lines that are vulnerable to disturb by erasing them deeper or shallower than the other word lines of the erase block.

28. The method of claim 21, wherein selecting two or more word line voltages for a plurality of word lines of an erase block that has been selected for erasure further comprises selecting two or more word line voltages for a plurality of word lines where the two or more word line voltages are selected to be less than or equal to a supply voltage.

29. A method of erasing an erase block of memory cells in an array of non-volatile memory cells, comprising:
applying a first voltage to one or more first word lines of an erase block, each first word line coupled to one or more of the non-volatile memory cells of the erase block;
applying a second voltage to one or more second word lines of the erase block, each second word line coupled to one or more of the non-volatile memory cells of the erase block; and
applying a third voltage to a substrate connection of the non-volatile memory cells;
wherein the second and third voltages are each different from the first voltage.

30. The method of claim 29, wherein the second and third voltages are each greater than the first voltage.

31. The method of claim 30, wherein the third voltage is greater than the second voltage.

32. The method of claim 29, wherein the first and third voltages are expected to cause erasure of a nominal memory cell of the erase block if applied across its word line and substrate connection.

33. The method of claim 29, wherein the first and second voltages are selected to be less than or equal to Vcc.

34. The method of claim 29, further comprising:
applying a fourth voltage to one or more third word lines of the erase block, each third word line coupled to one or more of the non-volatile memory cells;
wherein the fourth voltage is different from at least the first and second voltages.

35. A method of erasing memory cells in an erase block of an array of non-volatile memory cells, each memory cell coupled to a word line and to a substrate, the method comprising:
selecting a first word line voltage and a substrate voltage, wherein the first word line voltage and the substrate voltage are expected to cause erasure of a nominal memory cell of the non-volatile memory cells of the erase block if applied to its word line and the substrate, respectively;
selecting a second word line voltage, wherein the second word line voltage is different than the first word line voltage and where the second word line voltage and the substrate voltage are also expected to cause erasure of a nominal memory cell of the non-volatile memory cells of the erase block if applied to its word line and the substrate, respectively;
applying the first word line voltage to one or more first word lines of the erase block of non-volatile memory cells, wherein each first word line is coupled to one or more of the memory cells;
applying the second word line voltage to one or more second word lines of the erase block of non-volatile memory cells, wherein each second word line is coupled to one or more of the memory cells; and
applying the substrate voltage to the substrate of the erase block while applying the first and second word line voltages.

36. The method of claim 35, wherein the second word line voltage is greater than the first word line voltage.

37. The method of claim 36, wherein each second word line is coupled to memory cells expected to erase faster than memory cells coupled to the first word lines.

38. The method of claim 35, wherein the second word line voltage is less than the first word line voltage.

39. The method of claim 38, wherein each second word line is coupled to memory cells expected to erase slower than memory cells coupled to the first word lines.

40. A non-volatile memory device comprising:
a non-volatile memory array having a plurality of erase blocks; and
a control circuit, wherein the control circuit is adapted to erase a selected erase block of the non-volatile memory array by,
applying two or more voltages to a plurality of word lines, each word line coupled to one or more non-volatile memory cells of the selected erase block, and
applying an erase voltage to a substrate connection of the non-volatile memory cells of the erase block to erase the memory cells.

41. The non-volatile memory device of claim 40, wherein the non-volatile memory device is one of a NAND architecture Flash memory device and a NOR architecture Flash memory device.

42. The non-volatile memory device of claim 40, wherein the control circuit is adapted to apply two or more voltages to the plurality of word lines, where the voltages are selected based on physical characteristics of the plurality of word lines.

43. The non-volatile memory device of claim 42, wherein physical characteristics of the plurality of word lines are one of the erasure speed of each of the plurality of word lines, the resistance of each of the plurality of word lines, the coupling ratio of each of the plurality of word lines, and the cross-sectional area of each of the plurality of word lines.

44. The non-volatile memory device of claim 40, wherein the control circuit is adapted to apply two or more voltages to the plurality of word lines, where the voltages are selected based on an alternating pattern of wide and thin widths of the plurality of word lines of the erase block.

45. The non-volatile memory device of claim 40, wherein the control circuit is adapted to apply two or more voltages to the plurality of word lines, where the voltages are selected based on one of the erasure history of each of the plurality of word lines, and the placement of each of the plurality of word lines in the erase block.

46. The non-volatile memory device of claim 40, wherein the control circuit is adapted to apply two or more voltages to the plurality of word lines, where the voltages are selected to erase the non-volatile memory cells of one or more word lines deeper than the memory cells of other word lines for increased resistance disturb.

47. The non-volatile memory device of claim 40, wherein the control circuit is further adapted to:
erase verify the non-volatile memory cells coupled to the plurality of word lines;
adjust the two or more voltages applied to the plurality of word lines if the erase block fails erase verification; and
re-apply an erase voltage to a substrate connection of the non-volatile memory cells of the erase block to erase the memory cells.

48. The non-volatile memory device of claim 47, wherein the control circuit is adapted to repeat for one or more iteration cycles, until the erase block passes erase verification or a maximum number of iterations is reached.

49. A system comprising:
a host coupled to a non-volatile memory device, wherein the non-volatile memory device comprises,
a non-volatile memory array having a plurality of blocks;
wherein the system is adapted to erase a selected block of the non-volatile memory array by,
applying two or more voltages to a plurality of word lines, each word line coupled to one or more non-volatile memory cells of the selected block, and
applying an erase voltage to a substrate connection of the non-volatile memory cells of the block to erase the memory cells.

50. The system of claim 49, wherein the non-volatile memory device is one of a NAND architecture Flash memory device and a NOR architecture Flash memory device.

51. The system of claim 49, wherein the host is one of a processor and a memory controller.

52. The system of claim 49, wherein the system is adapted to apply two or more voltages to the plurality of word lines, where the voltages are selected based on one of the erasure speed of each of the plurality of word lines, the resistance of each of the plurality of word lines, the coupling ratio of each of the plurality of word lines, and the cross-sectional area of each of the plurality of word lines.

53. The system of claim 49, wherein the system is adapted to apply two or more voltages to the plurality of word lines, where the voltages are selected based on an alternating pattern of large and small word line cross-sectional areas of the plurality of word lines of the erase block.

54. The system of claim 49, wherein the system is adapted to apply two or more voltages to the plurality of word lines, where the voltages are selected based on one of the erasure history of each of the plurality of word lines, the erasure history of the erase block, and the placement of each of the plurality of word lines in the erase block.

55. The system of claim 49, wherein the system is adapted to apply two or more voltages to the plurality of word lines, where the voltages are selected to erase the non-volatile memory cells of one or more word lines deeper than the memory cells of other word lines for increased resistance disturb.

56. The system of claim 49, wherein the system is further adapted to:
erase verify the non-volatile memory cells coupled to the plurality of word lines;
adjust the two or more voltages applied to the plurality of word lines if the erase block fails erase verification; and
re-apply an erase voltage to a substrate connection of the non-volatile memory cells of the erase block to erase the memory cells.

57. The system of claim 56, wherein the system is adapted to repeat for one or more iteration cycles, until the erase block passes erase verification or a maximum number of iterations is reached.

58. The system of claim 49, wherein the system is adapted to apply an erase voltage to a channel of each of the non-volatile memory cells of the block to erase the memory cells.

59. A memory module, comprising:
at least one memory device containing an array with a plurality of non-volatile memory cells arranged in a plurality of erase blocks;
a housing enclosing the at least one memory device; and
a plurality of contacts configured to provide selective contact between the at least one memory device and a host system;
wherein the memory module is adapted to erase a selected erase block of the at least one memory device by,
applying two or more voltages to a plurality of word lines, each word line coupled to one or more non-volatile memory cells of the selected erase block, and
applying an erase voltage to a substrate connection of the non-volatile memory cells of the erase block to erase the memory cells.

60. The module of claim 59, further comprising a memory controller coupled to the at least one memory device for controlling operation of each memory device in response to the host system.

61. A method of operating a non-volatile memory device, comprising:
erasing a selected block of non-volatile memory cells utilizing a uniform word line voltage applied to a plurality of word lines of the block;
erase verifying the block of non-volatile memory cells; and
adjusting the voltages applied to one or more word lines of the block of non-volatile memory cells if the block fails erase verification.

62. The method of claim 61, wherein adjusting the voltages applied to one or more word lines of the block of non-volatile memory cells if the block fails erase verification further comprises adjusting the voltages applied to one or more word lines of the block of non-volatile memory cells if the block fails erase verification by adjusting the voltages applied to one or more word lines coupled to non-volatile memory cells that are failing erase verification.

63. The method of claim 62, wherein adjusting the voltages applied to one or more word lines of the block of non-volatile memory cells if the block fails erase verification further comprises adjusting the voltages applied to one or more word lines of the block of non-volatile memory cells to compensate one or more word lines that are erasing at one of a fast erasing speed than the other word lines of the block and a slow erasing speed than the other word lines of the block.

64. The method of claim 61, wherein the non-volatile memory device is one of a NAND architecture memory device and a NOR architecture memory device.

65. The method of claim 61, wherein the voltages applied to one or more word lines of the block of non-volatile memory cells are selected to be less than or equal to a supply voltage.

66. A method of operating a non-volatile memory device, comprising:
erasing a selected block of non-volatile memory cells utilizing a uniform word line voltage applied to a plurality of word lines of the block;
erase verifying the block of non-volatile memory cells; and
adjusting the voltages applied to one or more word lines of the block of non-volatile memory cells if the block fails erase verification based on characteristics of the block.

67. The method of claim 66, wherein adjusting the voltages applied to one or more word lines of the block of non-volatile memory cells if the block fails erase verification based on characteristics of the block further comprises adjusting the voltages applied to one or more word lines of the block of non-volatile memory cells utilizing design characteristics of the block.

68. The method of claim 67, wherein adjusting the voltages applied to one or more word lines of the block of non-volatile memory cells utilizing design characteristics of the block further comprises adjusting the voltages applied to one or more word lines of the block of non-volatile memory cells utilizing one of the erasure speed of each of the plurality of word lines, the resistance of each of the plurality of word lines, the coupling ratio of each of the plurality of word lines, the cross-sectional area of each of the plurality of word lines, and the placement of each of the plurality of word lines in the block.

69. The method of claim 66, wherein adjusting the voltages applied to one or more word lines of the block of non-volatile memory cells if the block fails erase verification based on characteristics of the block further comprises adjusting the voltages applied to one or more word lines of the block of non-volatile memory cells utilizing the erase history of the block.

70. The method of claim 69, wherein adjusting the voltages applied to one or more word lines of the block of non-volatile memory cells utilizing the erase history of the block further comprises adjusting the voltages applied to one or more word lines of the block of non-volatile memory cells utilizing the erase history of the plurality of word lines of the block.

71. The method of claim 66, wherein the non-volatile memory device is one of a NAND architecture memory device and a NOR architecture memory device.

72. The method of claim 66, wherein the voltages applied to one or more word lines of the block of non-volatile memory cells are selected to be less than or equal to a Vcc voltage.
